(19) United States
(12) Patent Application Publication
(10) Pub. No.: US 2026/0282343 A1
(43) Pub. Date: Sep. 17, 2026

(54) SEMICONDUCTOR DEVICE AND MANUFACTURE METHOD THEREOF

(71) Applicant: NANYA TECHNOLOGY CORPORATION, New Taipei city (TW)

(72) Inventor: Chung-Peng HAO, New Taipei City (TW)

(21) Appl. No.: 19/080,945

(22) Filed: Mar. 17, 2025

(51) Int. Cl. H10B 12/00

(52) U.S. Cl. CPC H10B 12/50; H10B 12/01; H10B 12/488

(57) ABSTRACT

A semiconductor device is provided, including: a substrate, a conductive contact, a metal plate, an array structure and a plurality of circuit structures. The substrate includes an array portion and a plurality of circuit portions neighboring to the array portion, wherein the array portion is located in an array area, and the plurality of circuit portions is located in a plurality of circuit areas. The conductive contact is disposed over the substrate. The metal plate is disposed on the conductive contact. The array structure is disposed over the metal plate. A plurality of circuit structures is disposed neighboring to the array structure. A method of manufacturing a semiconductor device is further provided.

### BACKGROUND

### Field of Invention

The present disclosure relates to a semiconductor device and a method of manufacturing a semiconductor device.

### Description of Related Art

Semiconductor devices are widely used in the electronics industry since semiconductor devices have relatively small size, multifunctional properties, and relatively low manufacturing costs. However, since the size of the semiconductor device shrinks, the space of the electrode connection structure for connecting to power supply is limited, the manufacture procedure thereof is burdensome, and voltage stability is instability since contacts connecting to the power supply is limited.

For the foregoing reason, there is a need to solve the above-mentioned problem by providing a semiconductor device with improved electrode connection structure for use in connection of power supply.

### SUMMARY

Some embodiments of the present disclosure provide a semiconductor device, including: a substrate, a conductive contact, a metal plate, an array structure and a plurality of circuit structures. The substrate includes an array portion and a plurality of circuit portions neighboring to the array portion, wherein the array portion is located in an array area, and the plurality of circuit portions is located in a plurality of circuit areas. The metal plate is disposed on the conductive contact. The array structure is disposed over the metal plate. A plurality of circuit structures is disposed neighboring to the array structure.

In some embodiments, the array structure includes a central array structure and a plurality of peripheral array structures, in which the plurality of peripheral array structures include a first array structure, a second array structure, a third array structure and a fourth array structure surrounding the central array structure.

In some embodiments, the conductive contact includes a plurality of first conductive contacts below the first array structure, a plurality of second conductive contacts below the second array structure, a plurality of third conductive contacts below the third array structure and a plurality of fourth conductive contacts below the fourth array structure.

In some embodiments, the plurality of first conductive contacts, the plurality of second conductive contacts, the plurality of third conductive contacts and the plurality of fourth conductive contacts are aligned in one line, respectively.

In some embodiments, in which at least one of the plurality of first conductive contacts, the plurality of second conductive contacts, the plurality of third conductive contacts and the plurality of fourth conductive contacts are aligned in multiple lines.

In some embodiments, when the array structure, the plurality of circuit structures and the metal plate are projected onto the substrate, respectively, a projection of the metal plate covers a projection of the array structure.

In some embodiments, the semiconductor device further includes a metal connector below the conductive contact.

In some embodiments, the semiconductor device further includes a power supply electrically connected to the metal connector.

In some embodiments, the power supply is disposed between the metal connector and substrate.

In some embodiments, the power supply is disposed out of a vertical projection area of the array structure projected on a plane parallel to the substrate.

Some embodiments of the present disclosure provide a method of manufacturing a semiconductor device, including: forming an array structure and forming a plurality of circuit structures neighboring to the array structure; providing a substrate, including an array portion and a plurality of circuit portions neighboring to the array portion, in which the array portion is located in an array area corresponding to the array structure, and the plurality of circuit portions is located in a plurality of circuit areas corresponding to the plurality of circuit structures; forming a conductive contact over the array portion; and disposing a metal plate below the array structure and over the conductive contact.

In some embodiments, a step of forming the array structure and a step of forming the plurality of circuit structures are performed together.

In some embodiments, a step of forming the plurality of circuit structures and a step of forming the conductive contact are performed separately.

In some embodiments, the plurality of array structures includes a central array structure and a plurality of peripheral array structures, in which the plurality of peripheral array structures include a first array structure, a second array structure, a third array structure and a fourth array structure surrounding a central array structure surrounding the central array structure.

In some embodiments, the conductive contact includes a plurality of first conductive contacts below the first array structure, a plurality of second conductive contacts below the second array structure, a plurality of third conductive contacts below the third array structure and a plurality of fourth conductive contacts below the fourth array structure.

In some embodiments, the plurality of first conductive contacts, the plurality of second conductive contacts, the plurality of third conductive contacts and the plurality of fourth conductive contacts are aligned in one line, respectively.

In some embodiments, at least one of the plurality of first conductive contacts, the plurality of second conductive contacts, the plurality of third conductive contacts and the plurality of fourth conductive contacts are aligned in multiple lines.

In some embodiments, when the array structure, the plurality of circuit structures and the metal plate are projected onto the substrate, respectively, a projection of the metal plate covers a projection of the array structure.

In some embodiments, the method further includes forming a metal connector over the array portion before a step of forming the conductive contact, and the step of forming the conductive contact includes forming the conductive contact over the metal connector.

In some embodiments, the method further includes electrically connecting a power supply to the metal connector.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 is a flow diagram illustrating a method of manufacturing a semiconductor device in accordance with some embodiments.

FIG. 2A is a top view illustrating the distribution of an array structure and a plurality of circuit structures at step S110 in the manufacturing of a semiconductor device in accordance with some embodiments of this disclosure.

FIGS. 2B-2F are cross-sectional views of various intermediary stages (step S120 to step S150) in the manufacturing of a semiconductor device in accordance with some embodiments of this disclosure, in which FIG. 2B is a cross-sectional view taken along line A-A′ of FIG. 2A.

FIG. 2G is a bottom view of step S150 of FIG. 1 in the manufacturing of a semiconductor device in accordance with some embodiments of this disclosure, in which the middle connection structure and the substrate are omitted for representing the location of the conductive contacts and the metal plate more clearly.

FIG. 2H and FIG. 2I are bottom views of the intermediary stage of step S150 of FIG. 1 in the manufacturing of a semiconductor device in accordance with some other embodiments of this disclosure, in which the middle connection layer and the substrate are omitted in the figure for representing the location of conductive contacts and the metal plate more clearly.

FIG. 3A is cross-sectional view of step S160 in the manufacturing of a semiconductor device in accordance with some embodiments of this disclosure.

FIG. 3B is a cross-sectional view of step S160 in the manufacturing of a semiconductor device in accordance with some other embodiments of this disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

The terminology used herein is for the purpose of describing particular example embodiments only and is not intended to be limiting of the present disclosure. Single forms used in the present specification such as “a”, “one” and “the” includes multiple forms such as “at least one”; “or” represents “and/or” unless described clearly. As used herein, the term “and/or” includes any and all combinations of one or more of the associated listed items. It will be further understood that the terms “comprises”, “comprising”, and/or “has”, “have”, “having” when used in this specification, specify the presence of stated features, areas, integers, steps, operations, elements, and/or components, but do not preclude the presence or addition of one or more other features, areas, integers, steps, operations, elements, components, and/or groups thereof.

Embodiments of the present disclosure are described herein with reference to top illustrations that are schematic illustrations of idealized embodiments of the present disclosure. As such, variations from the shapes of the illustrations as a result, for example, of manufacturing techniques and/or tolerances, are to be expected. Thus, embodiments of the present disclosure should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present disclosure.

Reference will now be made in detail to embodiments of the present disclosure, examples of which are described herein and illustrated in the accompanying drawings. While the disclosure will be described in conjunction with embodiments, it will be understood that they are not intended to limit the disclosure to these embodiments. Therefore, the scope of the present disclosure is to be limited only by the appended claims.

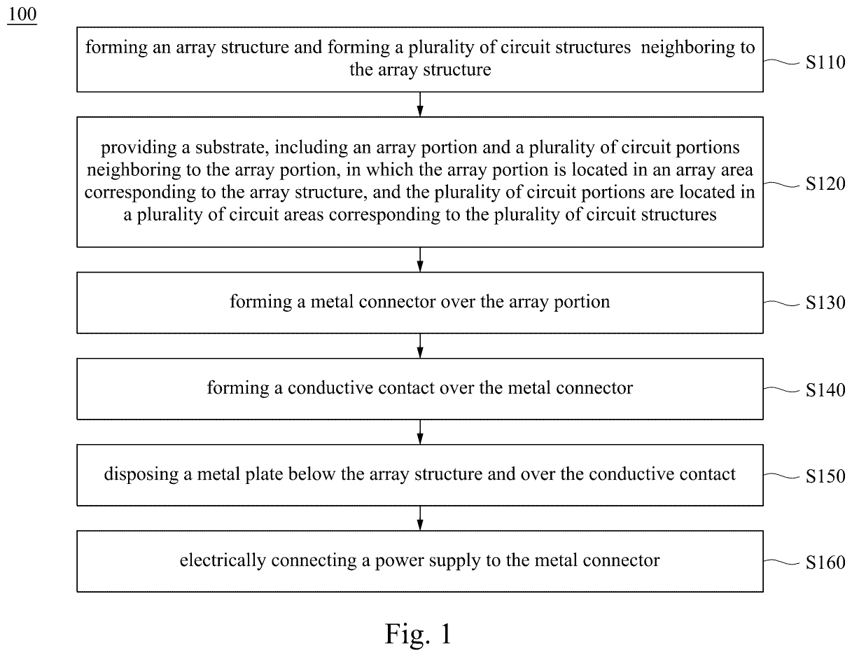

Referring to FIG. 1, illustrating a method 100 of manufacturing a semiconductor device, and the method 100 includes steps S110, S120, S130, S140, S150 and S160. The steps S110 to S160 of FIG. 1 are elaborated in connection with following figures, providing a semiconductor device with a bottom electrode connection structure (at least including the metal plate and the conductive contact) below the array structure. Through the disposition, more space for the bottom electrode connection structure can be released, voltage can be more stable since more conductive contacts are allowed to be disposed, and the structure and the procedure of the bottom electrode connection structure can be simplified without consideration of the position and the manufacture procedure of the array structure and the circuit structures.

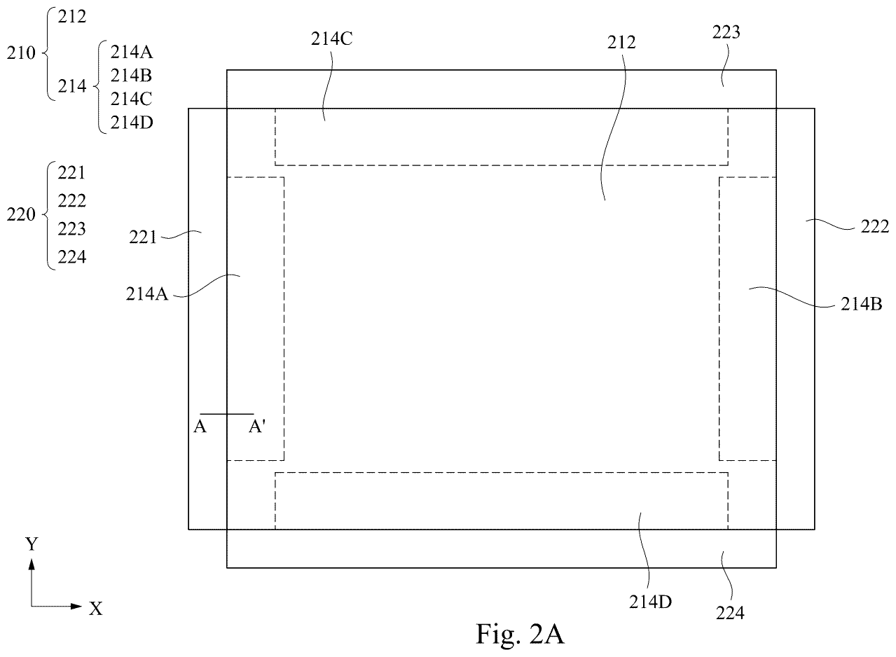

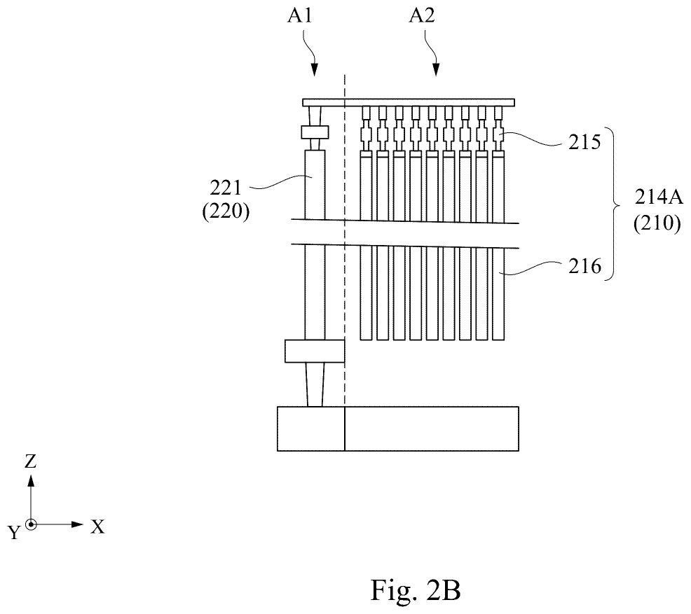

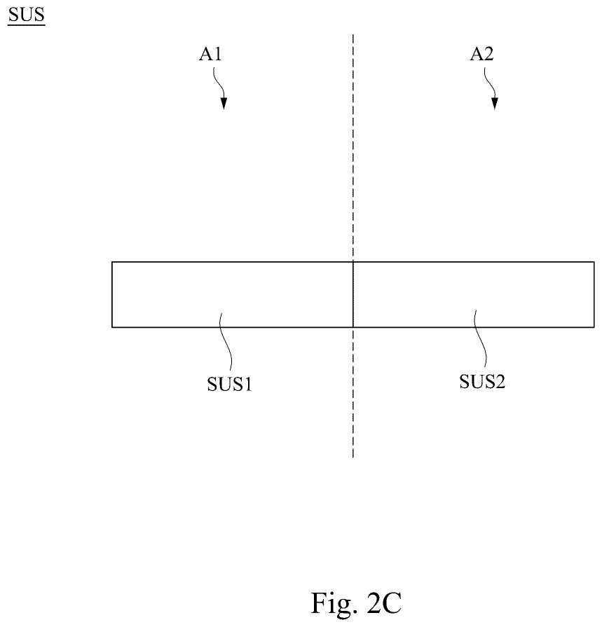

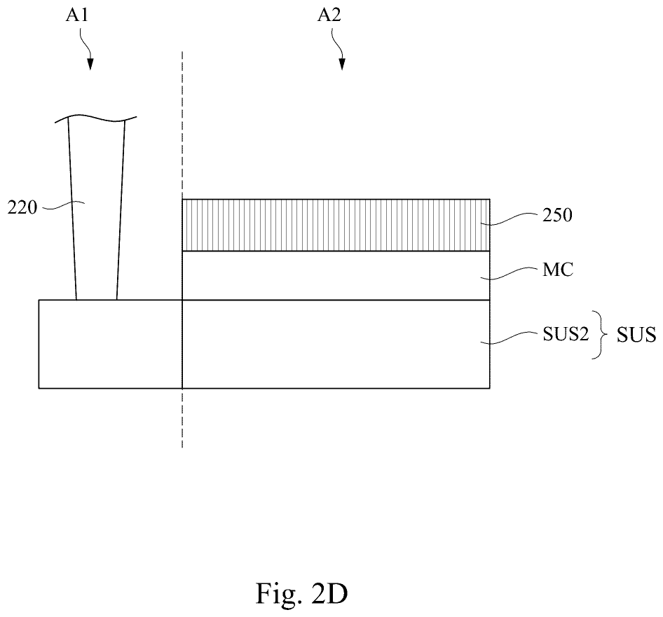

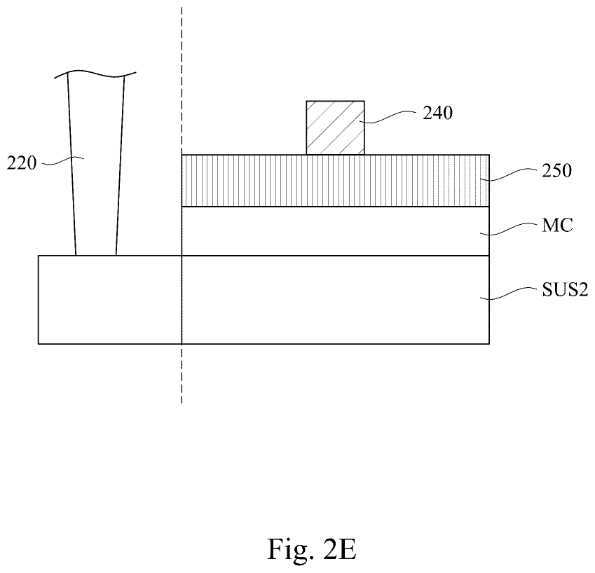

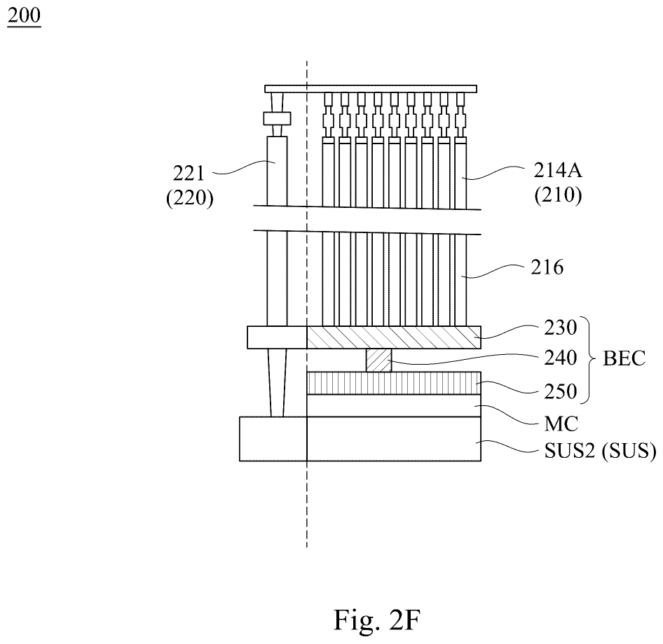

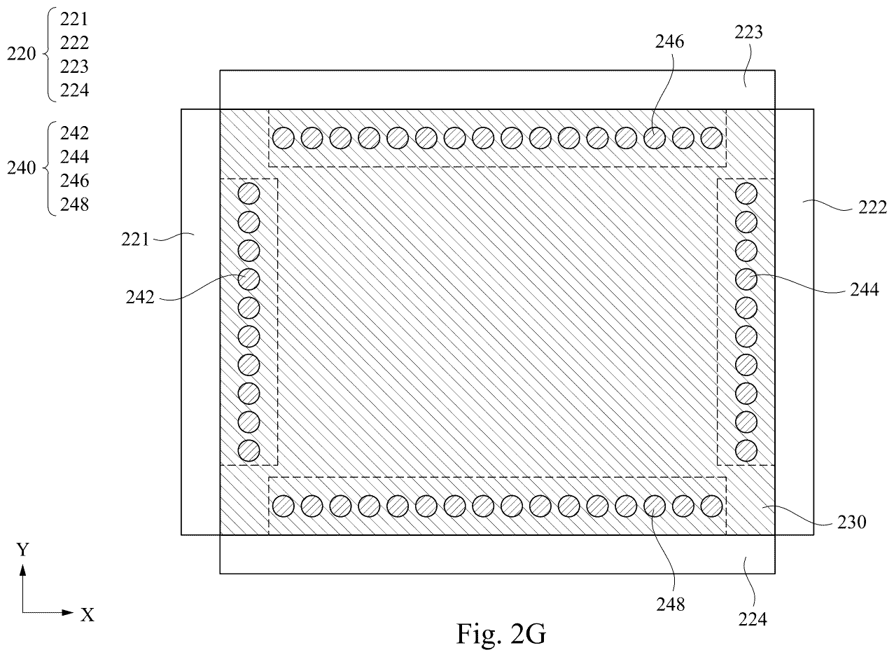

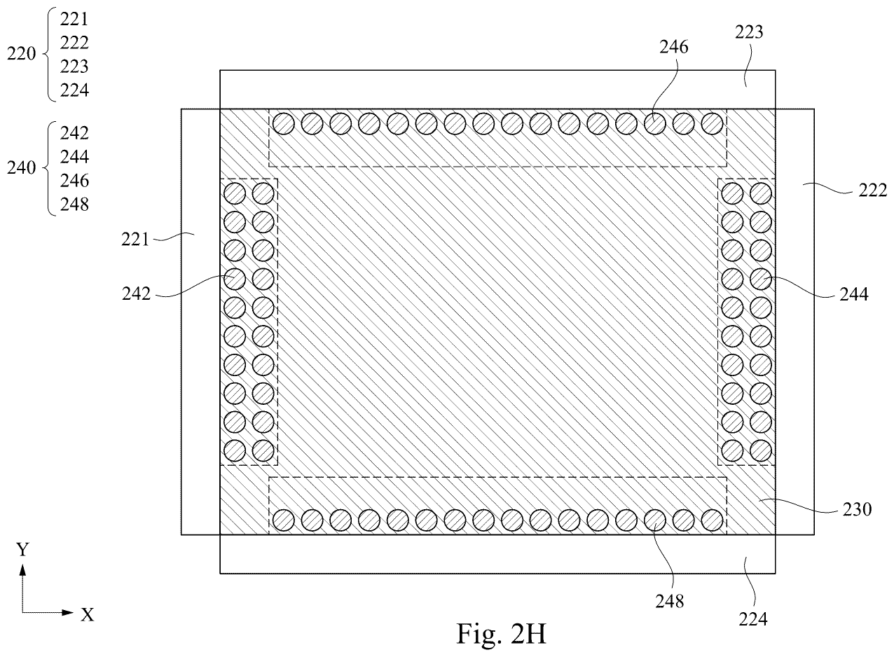

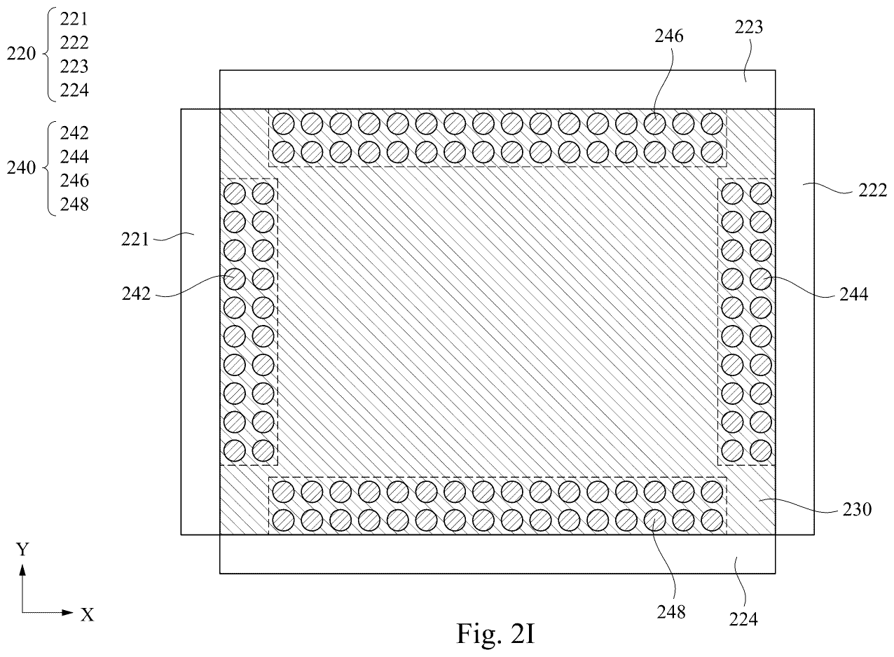

Referring to step S110 of FIG. 1 and FIG. 2A and FIG. 2B, in which FIG. 2A is a top view illustrating the distribution of an array structure 210 and a plurality of circuit structures 220 at step S110 in the manufacturing of a semiconductor device in accordance with some embodiments of this disclosure, and FIG. 2B is a cross-sectional view taken along line A-A′ of FIG. 2A. At step S110, an array structure 210 is formed and a plurality of circuit structures 220 neighboring to the array structure 210 is formed.

It is noted that the plurality of circuit structures 220 and the array structure 210 in FIG. 2B are simplified for making illustration easier. Other elements may also be included in the array structure 210 and the plurality of circuit structures 220 according to practical demands.

In some embodiments, the step of forming the array structure 210 and the step of forming the plurality of circuit structures 220 are performed together for making the procedure simpler and quickly.

In some embodiments, the array structure 210 includes a plurality of peripheral array structure 214 and a central array structure 212, in which the plurality of peripheral array structure 214 include a first array structure 214A, a second array structure 214B, a third array structure 214C and a fourth array structure 214D, and the first array structure 214A, the second array structure 214B, the third array structure 214C and the fourth array structure 214D surround the central array structure 212.

In some embodiments, the plurality of circuit structures 220 includes a first circuit structure 221, a second circuit structure 222, a third circuit structure 223 and a fourth circuit structure 224 surrounding the array structure 210, in which the first circuit structure 221 is neighboring to the first array structure 214A, the second circuit structure 222 is neighboring to the second array structure 214B, the third circuit structure 223 is neighboring to the third array structure 214C, and the fourth circuit structure 224 is neighboring to the fourth array structure 214D. In some embodiments, the plurality of circuit structures 220 is directly connected to a plurality of circuit portions SUS1 of a substrate SUS (please refer to FIG. 2C for details).

In some embodiments, please refer to FIG. 2B, the array structure 210 includes capacitors, transistors, or a combination thereof. In some embodiments, the first array structure 214A includes a conductive line 215 (such as a word line) and a capacitor 216 below the conductive line 215. In some embodiments, a bit line (not shown in FIG. 2B), vertical to the conductive line 215, is electrically connected to a channel, in which the channel is electrically connected to the capacitor 216, and a gate dielectric layer (not shown in FIG. 2B) is between the channel and the conductive line 215 (the word line). In some embodiments, the plurality of circuit structures 220 (such as the first circuit structure 221 in FIG. 2B) may be served as a sense amplifier or sub-word line driver.

In some embodiments, a vertical projection area of the array structure 210 and vertical projection areas of the plurality of circuit structures 220 projected on X-Y plane define a plurality of circuit areas A1 and an array area A2, respectively.

Referring to step S120 of FIG. 1 and FIG. 2C, in which FIG. 2C is a cross-sectional view of step S120 in the manufacturing of a semiconductor device in accordance with some embodiments of this disclosure. At step S120, a substrate SUS is provided, including an array portion SUS2 and a plurality of circuit portions SUS1 neighboring to the array portion SUS2, in which the array portion SUS2 is located in an array area A2 corresponding to the array structure 210 (FIG. 2B), and the plurality of circuit portions SUS1 is located in a plurality of circuit areas A1 corresponding to the plurality of circuit structures 220 (FIG. 2B).

In some embodiments, the plurality of circuit portions SUS1 and the array portion SUS2 are single substrate board, respectively. That is, the plurality of circuit portions SUS1 and the array portion SUS2 are not integrally formed.

In some embodiments, the substrate SUS includes a base material or structure on which materials are formed. In some embodiments, the substrate SUS may include a single material, multiple layers of different materials, one or more layers having regions of different materials or different structures therein, or other similar configurations. These materials may include semiconductors, insulators, conductors, or combinations thereof. In some embodiments, the substrate SUS may be a silicon substrate, a GaAs substrate, a SiGe substrate, a ceramic substrate, a quartz substrate, a glass substrate, a silicon on insulator (SOI) substrate, or the like. In some embodiments, the substrate SUS may include compound semiconductors (such as SiC, GaAs, GaP, InP, InAs or InSb) or alloy semiconductors (such as SiGe, GaAsP, AlInAs, AlGaAs, GaInAs, GaInP, or GaInAsP). In some embodiments, the substrate SUS includes a metal layer. In some embodiments, the substrate SUS is a multi-layer structure, including a polysilicon layer and a metal layer sequentially stacked on the polysilicon layer.

Referring to step S130 of FIG. 1 and FIG. 2D, in which FIG. 2D is a cross-sectional view of step S130 in the manufacturing of a semiconductor device in accordance with some embodiments of this disclosure. At step S130, a metal connector 250 is formed over the array portion SUS2.

In some embodiments, the metal connector 250 is only formed in the array area A2 and not extended to the plurality of circuit areas A1.

In some embodiments, the metal connector 250 includes tungsten, cobalt, zirconium, tantalum, titanium, aluminum, ruthenium, copper, tin, gold, metal carbides (e.g., tantalum carbide, titanium carbide, tantalum magnesium carbide), metal nitrides (e.g., titanium nitride), transition metal aluminides, or a combination thereof.

In some embodiments, a middle connection structure MC is disposed between the metal connector 250 and the substrate SUS. More particularly, the middle connection structure MC is disposed between the metal connector 250 and the array portion SUS2. In some embodiments, the middle connection structure MC can be single layer or multiple layers, so that the metal connector 250 is spaced apart from the substrate SUS by the middle connection structure MC.

Referring to step S140 of FIG. 1 and FIG. 2E, in which FIG. 2E is a cross-sectional view of step S140 in the manufacturing of a semiconductor device in accordance with some embodiments of this disclosure. At step S140, a conductive contact 240 is formed over the metal connector 250.

In some embodiments, the conductive contact 240 includes a conductive material, such as tungsten, cobalt, zirconium, tantalum, titanium, aluminum, ruthenium, copper, tin, gold, metal carbides (e.g., tantalum carbide, titanium carbide, tantalum magnesium carbide), metal nitrides (e.g., titanium nitride), transition metal aluminides, or a combination thereof.

In some embodiments, please refer to FIG. 1, FIG. 2B and FIG. 2E, a step of forming the array structure 210 and forming the plurality of circuit structures 220 (step S110) and a step of forming the conductive contact 240 over the metal connector 250 (step S140) are performed separately.

Please refer to FIG. 2B and FIG. 2E, it should be noted that the manufacture procedure of the conductive contact 240 and the manufacture procedure of the plurality of circuit structures 220 and the array structure 210 are independent and will not interfere with each other, and the structure and the manufacture procedure of the conductive contact 240 is independent from the plurality of circuit structures 220 and the array structure 210. Therefore, the structure and the manufacture procedure of the conductive contact 240 can be simplified.

Referring to step S150 of FIG. 1 and FIG. 2F, in which FIG. 2F is a cross-sectional view of step S150 in the manufacturing of a semiconductor device in accordance with some embodiments of this disclosure. At step S150, a metal plate 230 is disposed below the array structure 210 and over the conductive contact 240.

Therefore, a semiconductor device 200 including a bottom electrode connection structure BEC (including the metal plate 230, the conductive contact 240 and metal connector 250) is provided. The bottom electrode connection structure BEC is disposed below the array structure 210 for connecting the bottom electrode to the capacitor 216. In some embodiments, the bottom electrode connection structure BEC can be used in dynamic random access memory (DRAM), such as Oxide-semiconductor Channel Transistor Dynamic Random Access Memory (Oxide-semiconductor Channel Transistor DRAM, OCTRAM).

In some embodiments, the metal plate 230 includes tungsten, cobalt, zirconium, tantalum, titanium, aluminum, ruthenium, copper, tin, gold, metal carbides (e.g., tantalum carbide, titanium carbide, tantalum magnesium carbide), metal nitrides (e.g., titanium nitride), transition metal aluminides, or a combination thereof. Through the disposition of the metal plate 230, the bottom electrode connection structure BEC can be formed individually and the manufacture procedure will not be restricted to the disposition of the plurality of circuit structures 220 and the array structure 210.

In some embodiments, the metal plate 230 covers the entire array structure 210, but does not cover the plurality of circuit structures 220. That is, when the array structure 210, the plurality of circuit structures 220 and the metal plate 230 are projected onto the substrate SUS, respectively, a projection of the metal plate 230 covers a projection of the array structure 210, so as to defining the position of the bottom electrode connection structure BEC.

In some embodiments, the metal plate 230 is spaced apart from the substrate SUS at least by the conductive contact 240 and the metal connector 250, and the conductive contact 240 is spaced apart from the array portion SUS2 by the metal plate 230.

It is noted that contacts for connecting to a power supply in prior art is usually located at a remained space (such as corner space) of the array structure between the neighboring circuit structures. Therefore, a series of stacking contacts for pairing with the structure and the manufacture procedure of the circuit structures are required, which limits the space where the contacts could be disposed, limits the maximum occupied amount of the contacts and consumes burdensome procedures.

Through the disposition of the conductive contact 240, the bottom electrode connection structure BEC can be formed below the array structure 210 and will not be limited to the remaining space released according to the disposition of the plurality of circuit structures 220 (such as the corner space of the array structure 210 between the neighboring circuit structures 220). Therefore, the occupied space and the amount of the conductive contact 240 can be increased, thereby increasing voltage stability.

In some embodiments, the semiconductor device 200 is provided, including the substrate SUS, the middle connection structure MC, the metal connector 250, the conductive contact 240, the metal plate 230 and the array structure 210 from bottom to top, in which the plurality of circuit structures 220 is neighboring to the array structure 210. The metal connector 250 is disposed over the substrate SUS. The conductive contact 240 is disposed on the metal connector 250. The metal plate 230 is disposed on the conductive contact 240. The array structure 210 is disposed over the metal plate 230.

In some embodiments, one metal connector 250 directly interacts with multiple conductive contacts 240, instead of interacting with only one conductive contact 240, for simplifying the manufacture procedure of the bottom electrode connection structure BEC and defining the pathway of current transmission. For example, please refer to FIGS. 2G, 2H, and 2I.

In some embodiments, a thickness of the metal plate 230 is the same as a thickness of the element of the plurality of circuit structures 220 in the same layer.

Please refer to FIG. 2G, representing a bottom view of step S150 of FIG. 1 in the manufacturing of a semiconductor device 200 (FIG. 2F) in accordance with some embodiments of this disclosure, in which the middle connection structure MC and the substrate SUS (refer to FIG. 2F) are omitted for representing the location of conductive contacts 240 and the metal plate 230 more clearly.

In some embodiments, please refer to FIG. 2A and FIG. 2G, together, the conductive contact 240 includes a plurality of first conductive contacts 242 below the first array structure 214A, a plurality of second conductive contacts 244 below the second array structure 214B, a plurality of third conductive contacts 246 below the third array structure 214C and a plurality of fourth conductive contacts 248 below the fourth array structure 214D. Therefore, the plurality of first conductive contacts 242, the plurality of second conductive contacts 244, the plurality of third conductive contacts 246 and the plurality of fourth conductive contacts 248 can be disposed below the entire array structure 210, providing more space for conductive contacts 240 to be disposed, thereby increasing voltage stability.

In FIG. 2G, the plurality of first conductive contacts 242, the plurality of second conductive contacts 244, the plurality of third conductive contacts 246 and the plurality of fourth conductive contacts 248 are aligned in one line, respectively, in which each line extends along with the extension direction of the corresponding one of the peripheral array structure 214. Specifically, the plurality of first conductive contacts 242 and plurality of second conductive contacts 244 are aligned along Y-axis, and the plurality of third conductive contacts 246 and the plurality of fourth conductive contacts 248 are aligned along X-axis.

It's noted that different types of arrangements can be provided according to practical demands. In some other embodiments, at least one of the plurality of first conductive contacts 242, the plurality of second conductive contacts 244, the plurality of third conductive contacts 246 and the plurality of fourth conductive contacts 248 are aligned in multiple lines.

In some embodiments, the conductive contact 240 is not disposed below the plurality of circuit structures 220. For example, the conductive contact 240 is not disposed below any one of the first circuit structure 221, the second circuit structure 222, the third circuit structure 223 and the fourth circuit structure 224, thereby avoiding interfering the plurality of circuit structures 220.

Please refer to FIG. 2H, representing a bottom view of step S150 of FIG. 1 in the manufacturing of a semiconductor device in accordance with some other embodiments of this disclosure. In FIG. 2H, the plurality of first conductive contacts 242 and the plurality of second conductive contacts 244 are aligned in two lines along Y-axis, respectively, and the plurality of third conductive contacts 246 and the plurality of fourth conductive contacts 248 are aligned in single line along X-axis, respectively. Specifically, two of the plurality of first conductive contacts 242 and two of the plurality of second conductive contacts 244 are aligned along X-axis, and more than two of the plurality of first conductive contacts 242 and more than two of the plurality of second conductive contacts 244 are aligned along Y-axis.

Please refer to FIG. 2I, representing that the plurality of first conductive contacts 242, the plurality of second conductive contacts 244, the plurality of third conductive contacts 246 and the plurality of fourth conductive contacts 248 are aligned in two lines, respectively. In some other embodiments, multiple lines such as three lines, four lines, etc., can be provided.

Specifically, two of the plurality of first conductive contacts 242 and two of the plurality of second conductive contacts 244 are aligned along X-axis, and more than two of the plurality of first conductive contacts 242 and more than two of the plurality of second conductive contacts 244 are aligned along Y-axis. Two of the plurality of third conductive contacts 246 and two of the plurality of fourth conductive contacts 248 are aligned along Y-axis, and more than two of the plurality of third conductive contacts 246 and more than two of the plurality of fourth conductive contacts 248 are aligned along X-axis.

In some other embodiments, please refer to FIGS. 2A and 2I, together, the conductive contact 240 is not disposed below the entire peripheral array structure 214 (FIG. 2A). For example, the conductive contact 240 can be disposed below only one to three kinds of the first array structure 214A, the second array structure 214B, the third array structure 214C and the fourth array structure 214D according to practical demands.

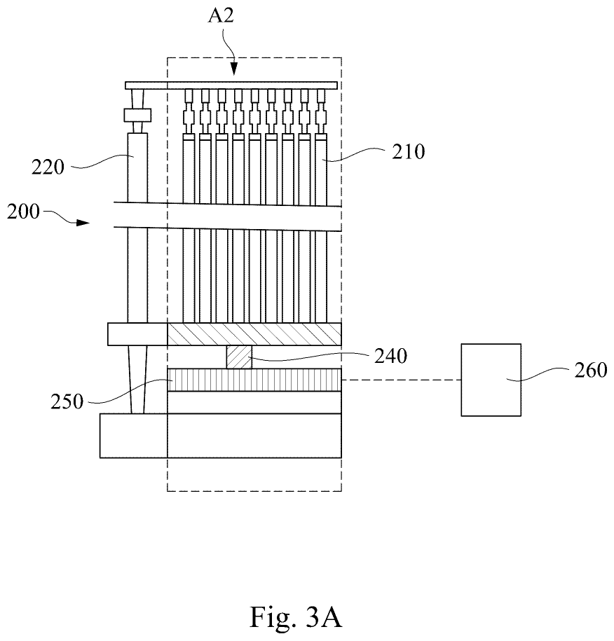

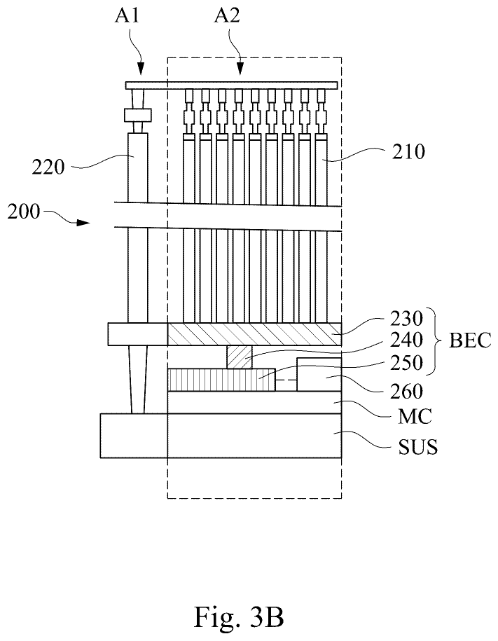

Referring to step S160 of FIG. 1 and FIG. 3A, in which FIG. 3A is a cross-sectional view of step 160 in the manufacturing of a semiconductor device 200 in accordance with some embodiments of this disclosure. At step S160, a power supply 260 is electrically connected to the metal connector 250.

In some embodiments, the power supply 260 includes various kinds of internal power supply device, such as common storage plate power supply (VPLT).

In some embodiments, the power supply 260 is not disposed in the array area A2. That is, the power supply 260 is substantially disposed out of the vertical projection area of the array structure 210 projected on a plane parallel to the substrate SUS. In some embodiments, the power supply 260 is substantially disposed out of the vertical projection area of the metal plate 230 projected on a plane parallel to the substrate SUS.

It's noted that different types of arrangements of the power supply 260 can be provided. In some other embodiments, please refer to FIG. 3B, the power supply 260 is disposed between the metal plate 230 and the substrate SUS (or more precisely, between the metal plate 230 and the middle connection structure MC), so as to save the occupied space of the power supply 260 in the working area and prevent from the interference of the array structure 210 and the plurality of circuit structures 220. For example, the power supply 260 is disposed in the array area A2 or in the plurality of circuit areas A1.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A semiconductor device, comprising:
a substrate, including an array portion and a plurality of circuit portions neighboring to the array portion, wherein the array portion is located in an array area, and the plurality of circuit portions are located in a plurality of circuit areas;
a conductive contact, disposed over the substrate;
a metal plate, disposed on the conductive contact;
an array structure, disposed over the metal plate; and
a plurality of circuit structures, disposed neighboring to the array structure.

2. The semiconductor device of claim 1, wherein the array structure comprises a central array structure and a plurality of peripheral array structures, wherein the plurality of peripheral array structures comprise a first array structure, a second array structure, a third array structure and a fourth array structure surrounding the central array structure.

3. The semiconductor device of claim 2, wherein the conductive contact comprises a plurality of first conductive contacts below the first array structure, a plurality of second conductive contacts below the second array structure, a plurality of third conductive contacts below the third array structure and a plurality of fourth conductive contacts below the fourth array structure.

4. The semiconductor device of claim 3, wherein the plurality of first conductive contacts, the plurality of second conductive contacts, the plurality of third conductive contacts and the plurality of fourth conductive contacts are aligned in one line, respectively.

5. The semiconductor device of claim 3, wherein at least one of the plurality of first conductive contacts, the plurality of second conductive contacts, the plurality of third conductive contacts and the plurality of fourth conductive contacts are aligned in multiple lines.

6. The semiconductor device of claim 1, wherein when the array structure, the plurality of circuit structures and the metal plate are projected onto the substrate, respectively, a projection of the metal plate covers a projection of the array structure.

7. The semiconductor device of claim 1, further comprising a metal connector below the conductive contact.

8. The semiconductor device of claim 7, further comprising a power supply electrically connected to the metal connector.

9. The semiconductor device of claim 8, wherein the power supply is disposed between the metal connector and substrate.

10. The semiconductor device of claim 8, wherein the power supply is disposed out of a vertical projection area of the array structure projected on a plane parallel to the substrate.

11. A method of manufacturing a semiconductor device, comprising:
forming an array structure and forming a plurality of circuit structures neighboring to the array structure;
providing a substrate, comprising an array portion and a plurality of circuit portions neighboring to the array portion, wherein the array portion is located in an array area corresponding to the array structure, and the plurality of circuit portions is located in a plurality of circuit areas corresponding to the plurality of circuit structures;
forming a conductive contact over the array portion; and
disposing a metal plate below the array structure and over the conductive contact.

12. The method of claim 11, wherein a step of forming the array structure and a step of forming the plurality of circuit structures are performed together.

13. The method of claim 11, wherein a step of forming the plurality of circuit structures and a step of forming the conductive contact are performed separately.

14. The method of claim 11, wherein the array structure comprises a central array structure and a plurality of peripheral array structures, wherein the plurality of peripheral array structures comprise a first array structure, a second array structure, a third array structure and a fourth array structure surrounding a central array structure surrounding the central array structure.

15. The method of claim 14, wherein the conductive contact comprises a plurality of first conductive contacts below the first array structure, a plurality of second conductive contacts below the second array structure, a plurality of third conductive contacts below the third array structure and a plurality of fourth conductive contacts below the fourth array structure.

16. The method of claim 15, wherein the plurality of first conductive contacts, the plurality of second conductive contacts, the plurality of third conductive contacts and the plurality of fourth conductive contacts are aligned in one line, respectively.

17. The method of claim 15, wherein at least one of the plurality of first conductive contacts, the plurality of second conductive contacts, the plurality of third conductive contacts and the plurality of fourth conductive contacts are aligned in multiple lines.

18. The method of claim 11, wherein when the array structure, the plurality of circuit structures and the metal plate are projected onto the substrate, respectively, a projection of the metal plate covers a projection of the array structure.

19. The method of claim 11, further comprising forming a metal connector over the array portion before a step of forming the conductive contact, and the step of forming the conductive contact comprises forming the conductive contact over the metal connector.

20. The method of claim 19, further comprising electrically connecting a power supply to the metal connector.
